(19) United States
(12) Patent Application Publication
(10) Pub. No.: US 2011/0298118 A1
(43) Pub. Date: Dec. 8, 2011

(54) SEMICONDUCTOR DEVICE

(75) Inventor: Takayuki YOSHIDA, Shiga (JP)

(73) Assignee: Panasonic Corporation, Osaka (JP)

(21) Appl. No.: 13/196,425

(22) Filed: Aug. 2, 2011

Related U.S. Application Data
(62) Division of application No. 12/368,763, filed on Feb. 10, 2009.

(30) Foreign Application Priority Data
May 28, 2008 (JP) 2008-139027

(51) Int. Cl. H01L 23/495

(52) U.S. Cl. 257/676; 257/E23.052

(57) ABSTRACT

A semiconductor device, including: a substrate having an upper face on which a first ground pad, a first power supply pad, a first signal pad, and a second signal pad are formed; a first substrate formed on the substrate and having an upper face on which a third signal pad connected to the first signal pad and a first circuit are formed; and a semiconductor element including a second substrate having a reverse face on which a bump electrode connected to the first circuit and a second circuit are formed and an upper face on which a fourth signal pad connected to the second signal pad is formed, with a signal through via connected to the second circuit and the fourth signal pad being buried in the second substrate.

### CROSS-REFERENCE TO RELATED APPLICATION

This application claims priority from Japanese Patent Application JP2008-139027 filed on May 28, 2008, the disclosure of which application is hereby incorporated by reference into this application in its entirety for all purposes.

### BACKGROUND OF THE INVENTION

The technology disclosed in this specification relates to a semiconductor device of a system-in-package (hereinafter “SiP”) architecture including a plurality of semiconductor elements mounted thereon, a circuit configuration thereof, and an electronic apparatus using the same.

For an electronic apparatus for processing high-definition videos, e.g., a high-vision digital TV, there is a demand for reducing the area of (i.e., downsizing) a semiconductor device used therein in order to reduce the size and cost of the product, and such an electronic apparatus employs an arrangement in which a plurality of semiconductor elements are put into a single package. For example, such a conventional semiconductor device has a following configuration.

A conventional semiconductor device includes a substrate, a first semiconductor element mounted on a first principal face of the substrate, a second semiconductor element mounted on a circuit formation face of the first semiconductor element with a circuit formation face (first principal face) of the second semiconductor element facing down, a first metal wire connecting an electrode pad on the first semiconductor element with an electrode pad formed on the substrate, a second metal wire connecting an electrode pad on a second principal face of the second semiconductor element with an electrode pad formed on the circuit formation face of the first semiconductor element, and a mold resin for encapsulating the first and second semiconductor elements.

In an SiP architecture, for the purpose of preventing a voltage drop in the central portion of the first semiconductor element while reserving the thermal dissipation performance, there is provided a through via formed by a conductor and running through the substrate of the second semiconductor element, wherein the through via is connected to a power supply pad or a ground (hereinafter “GND”) pad on the circuit formation face of the second semiconductor element. Moreover, the power supply pad or the GND pad on the second semiconductor element is connected to the power supply terminal or the GND terminal on the substrate by the second metal wire. Moreover, the through via is connected to a metal bump formed on the second principal face (reverse face) of the second semiconductor element, and the metal bump is connected to the power supply pad or the GND pad on the first semiconductor element. These techniques are described in Japanese Laid-Open Patent Publication Nos. 2007-59430 and 7-335826, for example.

With a structure where a plurality of semiconductor elements are stacked on one another on a substrate, and metal wires are used for the connection between semiconductor elements and between each semiconductor element and the substrate, with the semiconductor elements being entirely encapsulated in a mold resin, as in the conventional example above, it is possible to reduce the total area of a semiconductor device to be provided in an electronic apparatus and to reduce the production cost thereof. Moreover, a through via is provided running through the second semiconductor element, and the through via is connected to the power supply pad or the GND pad on the first semiconductor element via the power supply pad or the GND pad on the second semiconductor element and a metal bump on the first principal face of the second semiconductor element, with the power supply pad or the GND pad on the second semiconductor element being connected to the electrode pad or the GND pad on the substrate by a second metal wire. Moreover, the electrode pad formed on the circuit formation face of the second semiconductor element is connected to the electrode pad on the first semiconductor element by a third metal wire.

With this configuration, it is possible to efficiently supply a necessary voltage to the central portion of the first semiconductor element while reserving a sufficient thermal dissipation performance. Moreover, the total area of the elements to be mounted on the substrate can be reduced.

### SUMMARY OF THE INVENTION

However, minute processes have increased the functionality and the density of arrangement of circuit cells of semiconductor elements, particularly, logic circuit elements, and it is expected that more than 1000 electrodes are formed with a narrow pad pitch or in an area pad arrangement. Accordingly, there is a new structure proposed in the art, in which a logic element, as a second semiconductor element on the upper side, is mounted on a first semiconductor element or a silicon interposer by a flip chip technique, and wires are routed on the first semiconductor element or the underlying silicon interposer so that the pad pitch is widened to such an extent that wire bonding can be used. In such a case, however, the following problems may arise.

First, the signal of the interface terminal of the second semiconductor element, which handles a high-speed signal such as DDR, DDR2, DDR3 or LVDS, also propagates through the wiring portion on the underlying first semiconductor element or the silicon interposer, and the “RC time constant” between the wire resistance on the second semiconductor and the capacitance with respect to the Si substrate may cause a waveform distortion, whereby it is not possible to transmit the signal at a signal transfer rate as defined by the standard. This may lead to an erroneous operation of the semiconductor device, and hence the electronic apparatus.

In a conventional semiconductor device disclosed in Japanese Laid-Open Patent Publication No. 2007-59430, the power supply potential or the ground potential to the first semiconductor element is supplied only in one direction, i.e., in the direction coming from the second semiconductor element. Also when the power supply potential or the ground potential is supplied from the first semiconductor element to the second semiconductor element, the power supply potential or the ground potential to the logic element as the second semiconductor element is supplied only through the wires on each semiconductor element. Therefore, there is possibly a voltage drop due to the wire resistance or switching noise due to the inductance, and the logic element may operate erroneously due to the disturbance in the signal transfer or the disturbance in the power supply potential or the ground potential. This may lead to an erroneous operation of the semiconductor device, and hence the electronic apparatus.

It is an object of the present invention to provide a semiconductor device of an SiP architecture, wherein a signal from a second semiconductor element mounted on a first semiconductor element can be transmitted with a reduced distortion.

A semiconductor device of the present invention includes: a carrier having an upper face on which a first ground pad, a first power supply pad, a first signal pad, and a second signal pad are formed; a first substrate formed on the carrier and having an upper face on which a third signal pad connected to the first signal pad and a first circuit are formed; and a semiconductor element including a second substrate having a reverse face on which a bump electrode connected to the first circuit and a second circuit are formed and an upper face on which a fourth signal pad connected to the second signal pad is formed, with a signal through via connected to the second circuit and the fourth signal pad being buried in the second substrate. For example, the carrier may be a BGA substrate, a lead frame, or the like. The first substrate may be a semiconductor element, an interposer, or the like.

With this configuration, the signal of the semiconductor element is directly transmitted to the first signal pad via the signal through via without passing through wires on the first substrate. Thus, it is possible to realize a low-resistance, low-capacitance transmission line, and to reduce the waveform distortion by the RC time constant.

The semiconductor element further includes: a second ground pad formed on the upper face and connected to the first ground pad; a second power supply pad formed on the upper face and connected to the first power supply pad; a ground through via running through the second substrate and connected to the second ground pad; and a power supply through via running through the second substrate and connected to the second power supply pad. Thus, it is possible to reduce the impedance against the supply of the power supply voltage and the ground voltage, and to reduce simultaneous switching noise, etc., entailing a high-speed operation.

As described above, with the semiconductor device of the present invention, the high-speed transfer interface signal of the semiconductor element can be transmitted to the signal pad on the carrier via the signal through via and the signal pad without the signal passing through wires on the first substrate. Thus, it is possible to reduce the signal waveform distortion by the RC time constant.

### BRIEF DESCRIPTION OF THE DRAWINGS

FIG. 1 is a cross-sectional view schematically showing a semiconductor device according to a first embodiment of the present invention.

FIG. 2 is a plan view showing the semiconductor device of the first embodiment as viewed from above.

FIG. 3 is a plan view showing a semiconductor device according to a second embodiment of the present invention as viewed from above.

FIG. 4A is a diagram illustrating the effective inductance when in-phase signals are transmitted through adjacent wires, and FIG. 4B is a diagram illustrating the effective inductance of the semiconductor device of the present embodiment.

FIG. 5 is a plan view showing a semiconductor device according to an alternative embodiment of the present invention as viewed from above.

### DESCRIPTION OF THE PREFERRED EMBODIMENTS

Embodiments of the present invention will now be described with reference to the accompanying drawings.

### First Embodiment

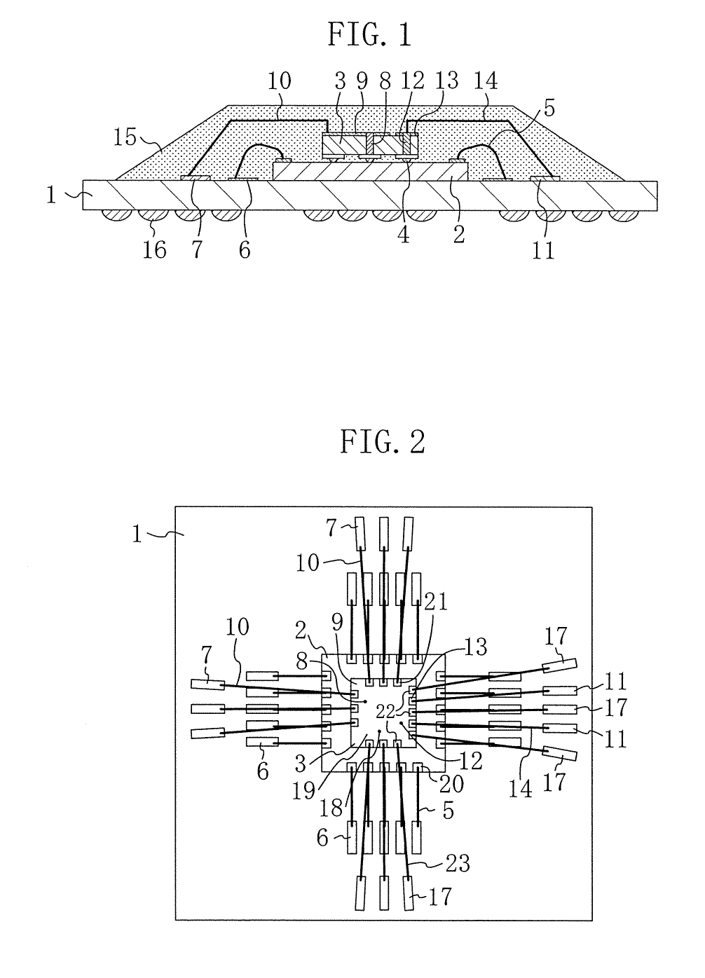

FIG. 1 is a cross-sectional view schematically showing a semiconductor device according to a first embodiment of the present invention, and FIG. 2 is a plan view showing the semiconductor device of the first embodiment as viewed from above. The mold resin is not shown in FIG. 2 for a better understanding of the structure.

As shown in FIGS. 1 and 2, the semiconductor device of the present embodiment includes a BGA substrate 1, a first semiconductor element 2, and a second semiconductor element 3. The BGA substrate 1 includes signal pads 6 and 11, GND pads 17 and power supply pads 7 formed on its upper face, and metal balls 16 formed on its reverse face. The first semiconductor element 2 is mounted on the upper face of the BGA substrate 1 with its circuit formation face facing up, and with signal pads 20 formed on its upper face (circuit formation face). The second semiconductor element 3 is mounted on the upper face of the first semiconductor element 2 with its circuit formation face facing down. The metal balls 16 are provided for the connection with the board terminals of the electronic apparatus. A silicon interposer including these pads may be used instead of the first semiconductor element.

The second semiconductor element 3 includes signal pads 13, power supply pads 21, GND pads 22, a GND conductor layer 19 and a power supply conductor layer 9 formed on its upper face, metal bumps 4 formed on its reverse face, a signal through via 12 running through the substrate for the connection between the signal pads 13 and the metal bumps 4, a power supply through via 8 running through the substrate for the connection between the power supply conductor layer 9 and the metal bumps 4, and a GND through via 18 for the connection between the GND conductor layer 19 and the metal bumps 4. The power supply pads 21 are connected to the power supply through via 8 via the power supply conductor layer 9, and the GND pads 22 are connected to the GND through via 18 via the GND conductor layer 19. The signal pads 11 and 13 are high-speed transfer interface pads. These pads are each provided along one side of a semiconductor element in a peripheral portion thereof. The second semiconductor element 3 is connected by a flip chip technique to the first semiconductor element 2 via the metal bumps 4 therebetween.

The semiconductor device also includes first wires 5 for the connection between the signal pads 20 on the first semiconductor element 2 and the signal pads 6 on the BGA substrate 1, second wires 10 for the connection between the power supply pads 7 and the power supply pads 21, third wires 14 for the connection between the signal pads 11 and the signal pads 13, fourth wires 23 for the connection between the GND pads 17 and the GND pads 22, and a mold resin 15 for encapsulating the first semiconductor element 2, the second semiconductor element 3, the first wires 5, the second wires 10, the third wires 14 and the fourth wires 23. The mold resin 15 protects the semiconductor elements and the wires from an external impact.

The signal pads 11 and the GND pads 17 alternate with each other, with each signal pad 11 being interposed between two GND pads 17, one on the left and one on the right.

Where a silicon interposer for supplying the signal of the second semiconductor element 3 and the power supply voltage or the ground voltage to an output or an element is used instead of the first semiconductor element 2, it is mounted so that the circuit face is facing up to be the upper face (the principal face that is farther away as viewed from the BGA substrate 1). Electrodes on the silicon interposer are connected to the metal bumps of the second semiconductor element 3. Such a silicon interposer may be a glass substrate, a ceramic substrate, an organic substrate, or the like.

For the connection between circuits formed on opposite faces of the second semiconductor element 3, any of various methods which have been proposed in the art may be employed. In some cases, a through via in the die edge portion is cut to its column direction and it is used for an electrical conductive pass.

In the semiconductor device of the present embodiment, the power supply potential and the ground potential are supplied from the first semiconductor element 2, the power supply pads 21 and the GND pads 22. Some of the electrode pads (the signal pads 6) around the first semiconductor element 2 are for GND or the power supply, and receive the supply of the ground potential or the power supply potential from the side of the BGA substrate 1. Moreover, the power is supplied directly from the reverse face of the second semiconductor element 3 into the circuit of the second semiconductor element 3 via the power supply through via 8 and the GND through via 18.

In a circuit handling high-speed signals, or the like, it is necessary that the power supply voltage or the ground voltage to be supplied remains stable while the circuit is in operation. With the semiconductor device of the present embodiment, employing such a structure as described above, it is possible to keep power supply lines impedance and GND lines impedance low, and to reduce simultaneous switching noise, etc., entailing a high-speed operation, thus realizing a stable operation of the semiconductor element. Therefore, the semiconductor device, and hence the electronic apparatus, can operate without erroneous operations.

Moreover, since the high-speed transfer interface signal of the second semiconductor element 3 can be connected to the signal pads 11 on the BGA substrate 1 via the signal through via 12, the signal pad 13 and the third wire 14, signals can be directly transmitted through low-resistance, low-capacitance wires without passing through wires on the first semiconductor element 2 or the silicon interposer. Therefore, it is possible to reduce the waveform distortion by the RC time constant, and to therefore transmit/receive signals at a signal transfer rate as defined by the standard.

While wires are used for the connection between the first semiconductor element 2 and the electrodes on the BGA substrate 1, through vias may be formed in the first semiconductor element 2, as are in the second semiconductor element 3, so that the through vias are connected to the electrodes on the BGA substrate 1.

In the semiconductor device of the present embodiment, the GND pads 22 are provided on both sides of each signal pad 13 on the second semiconductor element 3, and the GND pads 17 are provided on both sides of each signal pad 11 on the BGA substrate 1. Accordingly, the fourth wires 23 connected to the GND pads 17 are formed on both sides of each third wire 14 connected to the signal pad 11.

Where wires have a large inductance, the impedance of a wire becomes large as compared with the input/output impedance of the input/output buffer to cause reflection noise due to an impedance mismatch, whereby the signal waveform is likely to be distorted. Thus, an erroneous operation is likely to occur at the high-speed transfer interface. In high-speed transfer interface standards such as DDR, DDR2, DDR3 and direct RAMBUS, a so-called “common mode” is defined in which in-phase signals are transmitted through different wires. It is therefore believed that reducing the wire inductance as much as possible is effective in reducing the waveform distortion.

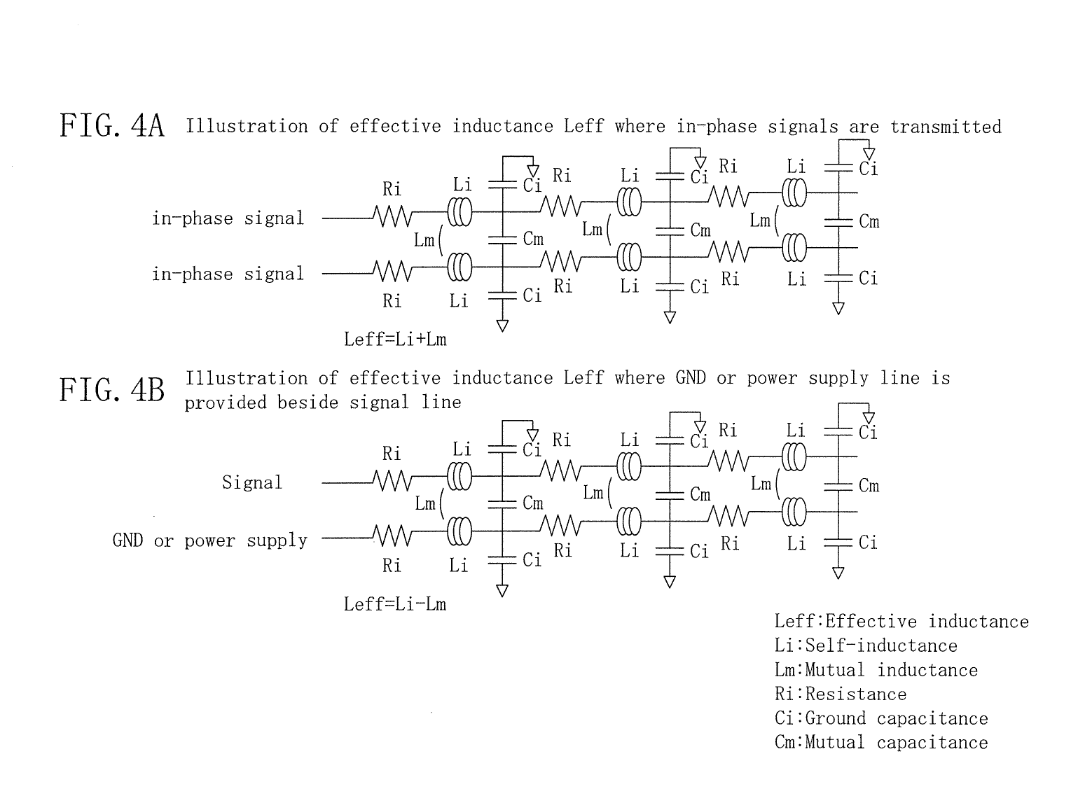

FIG. 4A is a diagram illustrating the effective inductance when in-phase signals are transmitted through adjacent wires, and FIG. 4B is a diagram illustrating the effective inductance of the semiconductor device of the present embodiment.

As shown in FIG. 4A, where in-phase signals are transmitted through adjacent lines, the effective inductance Leff is equal to the sum between the self-inductance Li of a line and the mutual inductance Lm between lines. In contrast, it is possible to virtually create a differential transmission state by providing a GND line or a power supply line adjacent to a signal line, as in the present embodiment shown in FIG. 4B, whereby the effective inductance Leff of the signal line is equal to the difference between the self-inductance Li of a line and the mutual inductance Lm between lines. Thus, it is possible to reduce the effective inductance of a line, and to thus reduce the signal waveform distortion. Therefore, it is possible to eliminate an erroneous operation at the high-speed interface, increasing the reliability of the semiconductor device, whereby the electronic apparatus can be operated without erroneous operations.

The present embodiment assumes a high-speed signal transfer interface in a common mode. Nevertheless, even with terminals for analog signals such as sound signals or video signals, a GND line or a power supply line may be provided on both sides of a signal line to achieve an electromagnetic separation between signal lines. This is effective in suppressing sound noise and video noise.

### Second Embodiment

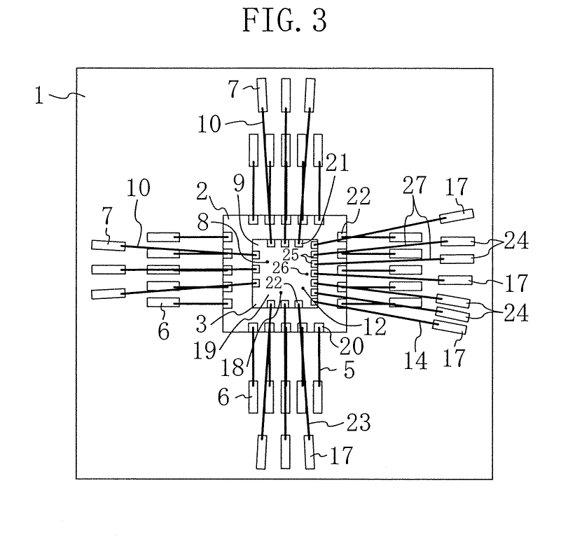

FIG. 3 is a plan view showing a semiconductor device according to a second embodiment of the present invention as viewed from above. In FIG. 3, like elements to those shown in FIGS. 1 and 2 are denoted by like reference numerals and will not be further described below.

As shown in FIG. 3, the semiconductor device of the present embodiment is a device for transmitting pairs of differential signals, such as LVDS, wherein GND lines or power supply lines are provided on both sides of a line pair for transmitting a differential signal pair, thereby achieving an electromagnetic separation between pairs of differential signals.

Pairs of differential signal pads 24, each including pads adjacent to each other for transmitting a differential signal pair, are provided on the BGA substrate 1 so that each pair of the differential signal pads 24 is interposed between the GND pads 17. Moreover, differential signal pads 25 are provided on the second semiconductor element 3, and a differential signal through via 26 is provided running through the substrate of the second semiconductor element 3 and connected to the differential signal pads 25. The GND pads 22 are provided so that each pair of the differential signal pads 25 is interposed therebetween.

With such a configuration, GND lines or power supply lines are provided on both sides of each differential transmission line pair so as to achieve an electromagnetic separation between pairs of differential signals, whereby it is possible to reduce external noise onto differential signal line pairs, and to reduce the waveform distortion of the differential signal pairs. Therefore, it is possible to reduce the erroneous operation at the high-speed interface, increasing the reliability of the semiconductor device, whereby the electronic apparatus can be operated without erroneous operations. The effective inductance Leff can be reduced also when there are provided lines adjacent to each other for the transmission of a pair of differential signals.

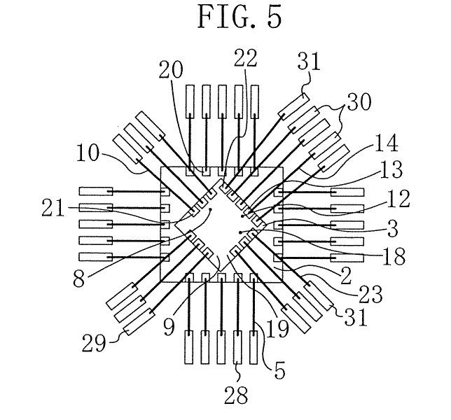

While the semiconductor device of the present embodiment uses the BGA substrate 1, the present invention is also applicable to a configuration using a lead frame. As shown in FIG. 5, the first semiconductor element 2 and the second semiconductor element 3 may be placed at an angle of 45 degrees with respect to each other as viewed from above so that the inner leads of the lead frames extend in eight directions as disclosed in Japanese Laid-Open Patent Publication No. 7-335826, whereby the inner leads of the first semiconductor element 2 are separated from those of the second semiconductor element 3. With such a structure, it is possible to avoid the waveform distortion due to signal interference between the first semiconductor element 2 and the second semiconductor element 3. In FIG. 5, reference numeral 28 denotes signal inner leads connected to the first wires 5 extending from the first semiconductor element 2, reference numeral 29 denotes power supply inner leads connected to wires extending from the second semiconductor element 3, reference numeral 30 denotes signal inner leads connected to the signal pads 13 of the second semiconductor element 3, and reference numeral 31 denotes GND inner leads connected to the GND pads 22.

As described above, the present invention is applicable to a semiconductor device in which semiconductor elements are stacked together, and any of various electronic apparatuses using the same.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

1-11. (canceled)

12. A semiconductor device, comprising:
a carrier having an upper face on which a first ground pad, a first power supply pad, a first signal pad, and a second signal pad are formed;
a first substrate formed on the carrier and having an upper face on which a third signal pad connected to the first signal pad and a first circuit are formed; and
a semiconductor element including a second substrate having a reverse face on which a bump electrode connected to the first circuit and a second circuit are formed and an upper face on which a fourth signal pad connected to the second signal pad is formed, with a signal through via connected to the second circuit and the fourth signal pad being buried in the second substrate,
wherein the semiconductor element further includes:
a second ground pad formed on the upper face and connected to the first ground pad,
a second power supply pad formed on the upper face and connected to the first power supply pad;
a ground through via running through the second substrate and connected to the second ground pad; and
a power supply through via running through the second substrate and connected to the second power supply pad, and where
the semiconductor element and the first substrate are placed at an angle of substantially 45 degrees with respect to each other as viewed from above.

13. The semiconductor device of claim 12, wherein the carrier is a lead frame, and the first power supply pad, the first signal pad and the second signal pad are each an inner lead, and
first portions of the inner leads connected to the first substrate and second portions of the inner leads connected to the semiconductor element are placed in eight directions.

14. The semiconductor device of claim 12, wherein:
a plurality of the first ground pads, a plurality of the first power supply pads, a plurality of the second ground pads and a plurality of the second power supply pads are provided;
the fourth signal pad is interposed between the second ground pads or the second power supply pads; and
the second signal pad is interposed between the first ground pads or the first power supply pads.

15. The semiconductor device of claim 12, wherein the fourth signal pad is an electrode pad for a DDR, DDR2 or DDR3 interface.

16. The semiconductor device of claim 14, wherein:
a plurality of the second signal pads and a plurality of the fourth signal pads are provided; and
in-phase signals are transmitted from the second signal pads to the corresponding fourth signal pads.

17. The semiconductor device of claim 12, wherein:
a plurality of the first ground pads, a plurality of the first power supply pads, a plurality of the second signal pads and a plurality of the fourth signal pads are provided;
a first signal line includes one of the second signal pads and one of the fourth signal pads connected thereto, and a second signal line includes another one of the second signal pads and another one of the fourth signal pads connected thereto, the first and second signal lines forming a pair of differential signal lines adjacent to each other carrying a pair of differential signals of different phases;
the second signal pad included in the first signal line and the second signal pad included in the second signal line are interposed between the first ground pads or the first power supply pads; and
the fourth signal pad included in the first signal line and the fourth signal pad included in the second signal line are interposed between the second ground pads or the second power supply pads.

18. The semiconductor device of claim 12, wherein the fourth signal pad is an electrode pad for an LVDS interface.

19. The semiconductor device of claim 12, wherein the carrier is a substrate having a ball electrode on its reverse face.

20. The semiconductor device of claim 12, wherein the carrier is a lead frame, and the first power supply pad, the first signal pad and the second signal pad are each an inner lead.

21. The semiconductor device of claim 12, wherein the first substrate is a semiconductor element including a circuit formed on its upper face.

22. The semiconductor device of claim 12, wherein the first substrate is a silicon interposer.
